(19) United States
(12) Patent Application Publication
(10) Pub. No.: US 2009/0045486 A1
(43) Pub. Date: Feb. 19, 2009

(54) Method of manufacturing nitride semiconductor device

(75) Inventor: Shinichi Kohda, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/219,692

(22) Filed: Jul. 25, 2008

(30) Foreign Application Priority Data
Jul. 27, 2007 (JP) 2007-196424

(51) Int. Cl. H01L 29/20; H01L 21/304

(52) U.S. Cl. 257/615; 438/462; 257/E21.238; 257/E29.089

(57) ABSTRACT

A method of manufacturing a nitride semiconductor device includes the steps of: forming a mask of a pattern selectively covering a cutting line on a first major surface of a substrate; forming group III nitride semiconductor layers exposing the mask provided on the cutting line by selectively growing a group III nitride semiconductor from exposed portions of the first major surface of the substrate; forming a division guide groove on the substrate along the cutting line; and dividing the substrate along the division guide groove. The step of forming the division guide groove may be a step of forming the division guide groove by laser processing.

### BACKGROUND OF THE INVENTION

1. Field of the Invention

The present invention relates to a method of manufacturing a nitride semiconductor device employing a group III nitride semiconductor. Group III nitride semiconductors are group III-V semiconductors employing nitrogen as a group V element, and typical examples thereof include aluminum nitride (AlN), gallium nitride (GaN) and indium nitride (InN), which can be generally expressed as AlₓIn_{y}Ga_{1-x-y}N (0≦x≦1, 0≦y≦1 and 0≦x+y≦1).

2. Description of Related Art

A semiconductor device having a structure obtained by growing a group III nitride semiconductor layer on a sapphire substrate is known in general. Typical examples thereof include a blue light emitting diode and a blue semiconductor laser. In addition to such light emitting devices, the group III nitride semiconductors are applied to transistors such as a power transistor and a high electron mobility transistor.

In the case of the light emitting device, the group III nitride semiconductor layer has a multilayer structure obtained by stacking an n-type GaN layer, an active layer (light emitting layer) and a p-type GaN layer from a side of the sapphire substrate, for example. According to this structure, electrons and positive holes are recombined in the active layer, to emit light.

In the steps of manufacturing the light emitting device, the group III nitride semiconductor layer is grown on a sapphire wafer, and the wafer provided with the group III nitride semiconductor is thereafter divided into individual devices.

### SUMMARY OF THE INVENTION

The substrate material (sapphire, for example) and the group III nitride semiconductor have different cleavage directions, due to lattice mismatching. According to a general technique of breaking the substrate along a scribing line formed thereon, therefore, the chip shape cannot be stabilized and the yield is deteriorated due to different cleavability of the substrate and the group III nitride semiconductor layer. In other words, a section of the group III nitride semiconductor layer is destabilized if the scribing line is formed on the wafer, while a section of the wafer is destabilized if the scribing line is formed on the group III nitride semiconductor layer.

Accordingly, an object of the present invention is to provide a method of manufacturing a nitride semiconductor device capable of stabilizing the chip shape, thereby improving the yield.

A method of manufacturing a nitride semiconductor device according to one aspect of the present invention includes the steps of: forming a mask of a pattern selectively covering a cutting line on a first major surface of a substrate; forming group III nitride semiconductor layers exposing the mask provided on the cutting line by selectively growing a group III nitride semiconductor from exposed portions of the first major surface of the substrate; forming a division guide groove on the substrate along the cutting line; and dividing the substrate along the division guide groove.

The substrate may be formed by a homogenous substrate made of a group III nitride semiconductor or a heterogeneous substrate made of a material other than the group III nitride semiconductor, so far as the group III nitride semiconductor can be epitaxially grown on the major surface thereof. Examples of the heterogeneous substrate include a sapphire substrate and an SiC substrate.

According to the present invention, the mask of the pattern covering the cutting line is formed on the first major surface of the substrate, and the group III nitride semiconductor layers are formed by selectively growing the group III nitride semiconductor from the portions of the major surface of the substrate exposed from the mask. These group III nitride semiconductor layers expose the mask covering the cutting line. Therefore, no group III nitride semiconductor layer is formed on the cutting line. When the division guide groove is formed on the substrate along the cutting line and the substrate is thereafter divided, therefore, only the substrate is divided, and the group III nitride semiconductor layers remain undivided. In other words, the group III nitride semiconductor layers are formed in an already separated state in the selective growth thereof, and may not be divided afterwards.

The sectional shape of the divided substrate provided with the division guide groove is stable. The shapes of the end faces of the group III nitride semiconductor layers not influenced by the division of the substrate are also stable. Thus, a chip having end faces of stable shapes can be obtained, whereby the yield can be improved.

Preferably, the step of forming the division guide groove includes a step of forming the division guide groove by laser processing. According to this method, the division guide groove is formed by laser processing, whereby the width of the division guide groove can be reduced. Therefore, the distance between the group III nitride semiconductor layers adjacent to each other on the substrate can be reduced, whereby the areas of the group III nitride semiconductor layers can be widened accordingly.

The step of forming the division guide groove may include a step of forming the division guide groove with a diamond cutter. According to this method, the division guide groove is defined by a scribing line formed by the diamond cutter. Therefore, the processing for forming the division guide groove can be performed with an apparatus having a simple structure.

The step of forming the division guide groove may include a step of forming the division guide groove by dicing. According to this method, the division guide groove is formed by the dicing generally employed for dividing a semiconductor wafer. In this case, the division guide groove may have a depth reaching an intermediate portion of the substrate along the thickness direction, or a depth extending over the substrate along the thickness direction. When the division guide groove has the depth extending over the substrate along the thickness direction, the step of dividing the substrate is carried out in the final stage of the step of forming the division guide groove.

The step of forming the division guide groove may include a step of forming the division guide groove on the first major surface of the substrate. According to this method, the division guide groove is formed on the substrate from the major surface on which the group III nitride semiconductor layers are formed in the state separated along the cutting line. Therefore, the processing step for forming the division guide groove can be easily carried out.

The step of forming the division guide groove may include a step of forming the division guide groove on a second major surface of the substrate. According to this method, the division guide groove is formed on the substrate from the major surface on which the group III nitride semiconductor layers are not formed. Therefore, the group III nitride semiconductor layers can be inhibited or prevented from influence by the processing for forming the division guide groove.

In order to correctly align the position (cutting line) where the group III nitride semiconductor layers are separated and the position of the division guide groove with each other, a transparent substrate is preferably employed as the substrate. In this case, the position for forming the division guide groove is preferably set while observing a dividing line (portion where the mask is exposed from the group III nitride semiconductor layers) through the substrate from the side of the second major surface of the substrate.

The foregoing and other objects, features and effects of the present invention will become more apparent from the following detailed description of the preferred embodiments with reference to the attached drawings.

### BRIEF DESCRIPTION OF THE DRAWINGS

FIGS. 1(a) to 1(d) are schematic diagrams successively showing the steps of manufacturing a nitride semiconductor device according to a first embodiment of the present invention.

FIG. 2 is a schematic perspective view of a sapphire wafer employed for manufacturing the nitride semiconductor device.

FIG. 3 is a diagram for illustrating a method of manufacturing a nitride semiconductor device according to a second embodiment of the present invention, showing a step of forming division guide grooves.

FIG. 4 is a diagram for illustrating a method of manufacturing a nitride semiconductor device according to a fourth embodiment of the present invention, showing a step of forming division guide grooves.

FIG. 5 is a diagram for illustrating a method of manufacturing a nitride semiconductor device according to a fifth embodiment of the present invention, showing a step of forming division guide grooves.

### DETAILED DESCRIPTION OF PREFERRED EMBODIMENTS

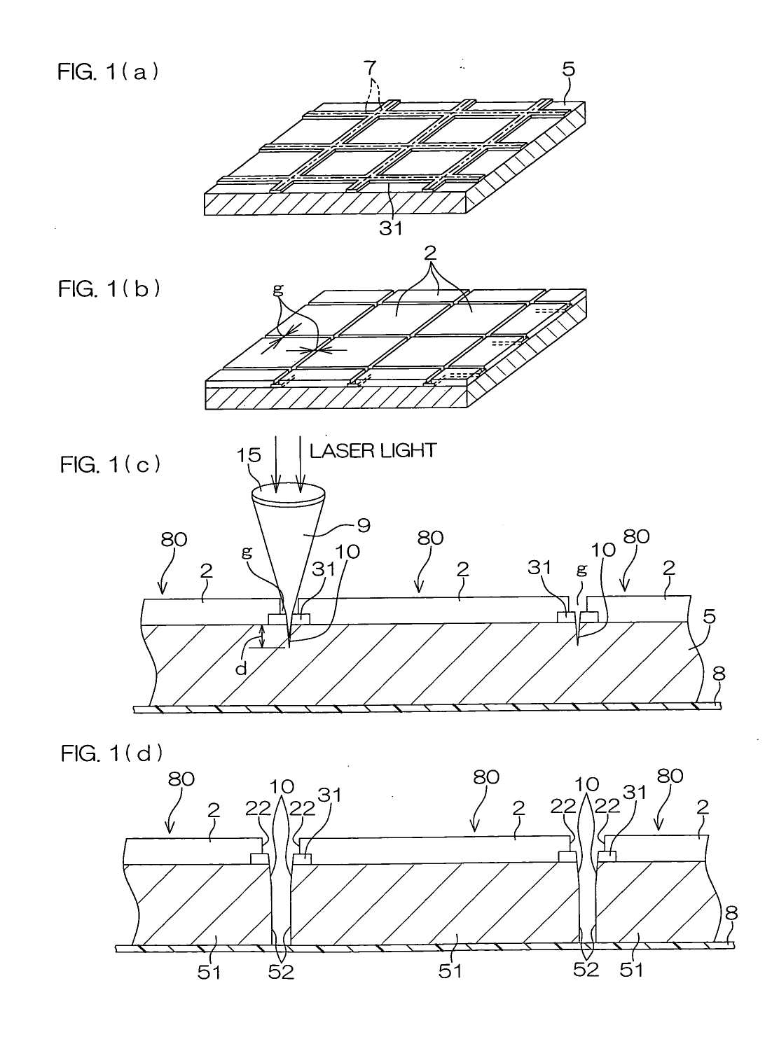

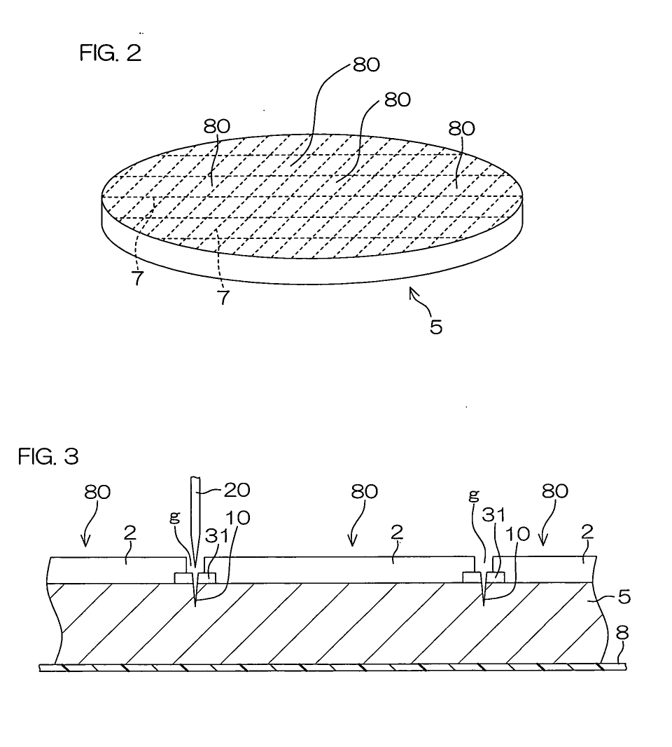

FIGS. 1(a) to 1(d) are schematic diagrams successively showing the steps of manufacturing a nitride semiconductor device according to a first embodiment of the present invention, and FIG. 2 is a schematic perspective view of a sapphire wafer 5 employed for manufacturing the nitride semiconductor device. The sapphire wafer 5 is in the form of a generally circular plate as shown in FIG. 2, while FIGS. 1(a) and 1(b) show a partial rectangular region thereof.

Individual devices 80 are formed on a plurality of individual device regions arranged on the sapphire wafer 5 in the form of a lattice respectively, and the sapphire wafer 5 is thereafter divided such that the individual devices 80 are cut out into chips. The individual device regions are rectangular regions partitioned along tessellated virtual cutting lines 7.

First, a mask 31 is formed on a first major surface of the sapphire wafer 5, as shown in FIG. 1(a). The mask 31 is made of silicon oxide, for example. This mask 31 is formed in a pattern selectively covering the cutting lines 7 and regions of a prescribed width located on both sides of the cutting lines 7 through a photolithographic step. Therefore, the mask 31 consists of strip-shaped portions covering the cutting lines 7, and forms a tessellated pattern as a whole. Further, the mask 31 partitions the plurality of rectangular individual device regions, and the sapphire wafer 5 is exposed on the individual device regions. The width of the strip-shaped portions of the mask 31 is 10 μm to 20 μm, for example. The thickness of the mask 31 is set to 2000 Å to 3000 Å, for example.

Then, group III nitride semiconductor layers 2 are epitaxially grown from the exposed regions of the sapphire wafer 5, as shown in FIG. 1(b). The group III nitride semiconductor layers 2 are selectively epitaxially grown on regions other than those covered with the mask 31. When reaching the thickness of the mask 31, the group III nitride semiconductor layers 2 are grown also on regions located on the mask 31. This selective growth of the group III nitride semiconductor layers 2 is stopped in a state where gaps g smaller than the width of the mask 31 are ensured between the group III nitride semiconductor layers 2, 2 grown from the adjacent ones of the individual device regions. Thus, the plurality of group III nitride semiconductor layers 2 separated from one another are formed on the individual device regions respectively.

In order to prepare a light emitting diode, for example, each group III nitride semiconductor layer 2 is formed by successively epitaxially growing an n-type GaN buffer layer (2 μm, for example) in contact with the sapphire wafer 5, an n-type GaN contact layer (1 μm to 10 μm, for example) stacked on the n-type GaN buffer layer, an active layer (light emitting layer) stacked on the n-type GaN contact layer and a p-type GaN contact layer (0.2 μm to 1 μm, for example) stacked on the active layer. For example, the active layer may have an MQW (multiple quantum well) structure (having a thickness of 0.05 μm to 0.3 μn total, for example) formed by alternately stacking quantum well layers consisting of InGaN layers (1 nm to 3 nm each, for example) and barrier layers consisting of non-doped GaN layers (10 nm to 20 nm each, for example) in a repetitive manner (3 to 8 cycles, for example).

Then, the thickness of the sapphire wafer 5 is reduced by grinding or polishing (chemical mechanical polishing, for example). For example, the sapphire wafer 5 has a thickness of about 350 μm, for example, in the initial stage, and this thickness is reduced to about 80 μm. The thickness of each group III nitride semiconductor layer 2 is about 2 μm to 3 μm, for example.

Then, division guide grooves 10 are formed on the sapphire wafer 5 along the cutting lines 7 (see FIG. 1(a)), as shown in FIG. 1(c). According to this embodiment, the processing for forming the division guide grooves 10 is performed with a laser processor.

While detailed illustration of the structure is omitted, the laser processor includes a laser beam generating unit, a laser application head including a converging lens 15 converging a laser beam 9 generated from the laser beam generating unit and an X-Y stage mechanism. FIG. 1(c) shows only the condensing lens 15 among these elements. A YAG laser or an excimer laser, for example, can be employed as the laser beam generating unit. The X-Y stage mechanism includes a stage holding the wafer 5 through a support sheet 8 and a moving mechanism two-dimensionally moving this stage in two orthogonal directions X and Y (horizontal directions, for example). The X-Y stage mechanism may further include a mechanism for moving the stage along a direction Z (vertical direction, for example) approximating/separating the stage to/from the converging lens 15, if necessary. The converging lens 15 is capable of converging the laser beam 9, and the focal length thereof may be rendered adjustable, if necessary. The distance between the converging lens 15 and the wafer 5 may be adjusted by approximating/separating the converging lens 15 to/from the stage of the X-Y stage mechanism, or by approximating/separating the stage of the X-Y stage mechanism to/from the converging lens 15. Thus, the positional relation between a focal point of the converging lens 15 and the wafer 5 can be adjusted. This positional relation can be adjusted by adjusting a focal length of the converging lens 23, as a matter of course.

The laser processor having the aforementioned structure scans the sapphire wafer 5 with the laser beam 9. More specifically, the laser processor scans the mask 31 with the laser beam 9 along the cutting lines 7.

In the scanning process, the laser beam 9 may be regularly applied to the sapphire wafer 5, or the laser beam generating unit may be on-off controlled so as to intermittently apply the laser beam 9.

On each position irradiated with the laser beam 9, the laser beam 9 is converged on and absorbed in the surface of the mask 31 so that a groove is formed in the mask 31, and this groove passes through the mask 31 to form a groove in the sapphire wafer 5. The focal point is scanned along the surface of the wafer 5, whereby a division guide groove 10 is formed on the boundary between each adjacent pair of individual devices 80 along the corresponding cutting line 7. The division guide grooves 10 are continuously formed if the laser beam 9 is regularly applied in the scanning process, while the division guide grooves 10 divided in a perforated manner at prescribed intervals in the scanning direction are formed if the laser beam 9 is intermittently applied in the scanning process.

No group III nitride semiconductor layers 2 are formed on the cutting lines 7, on which the mask 31 is formed. Further, the gaps g (5 μm each, for example) larger than the width (2 μm to 3 μm, for example) of the processing with the laser beam 9 are ensured between the group III nitride semiconductor layers 2, 2 adjacent to one another through the cutting lines 7. The processing with the laser beam 9 is performed through the gaps g, whereby the division guide grooves 10 are formed so as to reach the major surface of the sapphire wafer 5 through the mask 31 and to further reach portions of a prescribed depth d (2 μm to 3 μm, for example) from the major surface of the sapphire wafer 5.

When scanning the sapphire wafer 5 with the laser beam 9, the X-Y stage mechanism of the laser processor moves the stage holding the sapphire wafer 5 in the directions X and Y, so that the division guide grooves 10 are formed along the cutting lines 7. Thus, the laser processor scans the sapphire wafer 5 with the laser beam 9 along the cutting lines 7, thereby forming the division guide grooves 10 along the cutting lines 7. The cutting lines 7 are virtual lines tessellating the sapphire wafer 5, whereby the division guide grooves 10 are formed on the first major surface of the sapphire wafer 5 in a tessellated manner.

Then, a step of dividing the sapphire wafer 5 is carried out, as shown in FIG. 1(d). More specifically, external force perpendicular to the major surface of the sapphire wafer 5 is applied to the sapphire wafer 5 along the cutting lines 7. Thus, the sapphire wafer 5 is divided along the division guide grooves 10. The plurality of chip-like individual devices 80 are cut out from the sapphire wafer 5 in this manner.

According to this embodiment, as hereinabove described, the mask 31 having the pattern selectively covering the cutting lines 7 is formed on the first major surface of the sapphire wafer 5, and the group III nitride semiconductor layers 2 are selectively epitaxially grown from the surface portions of the sapphire wafer 5 exposed from the mask 31. Then, the division guide grooves 10 are formed on the sapphire wafer 5 along the cutting lines 7. When the sapphire wafer 5 is divided along the division guide grooves 10, divided sapphire substrates 51 have excellent cut end faces 52. Further, no group III nitride semiconductor layers 2 are formed on the cutting lines 7, but the group III nitride semiconductor layers 2 are originally formed on the individual device regions in the states separated from one another. Therefore, the shapes of end faces 22 of the group III nitride semiconductor layers 2 are not influenced by the division of the sapphire wafer 5. Thus, nitride semiconductor devices having end faces of stable shapes can be so formed that the yield can be improved.

While the cut end faces 52 of the sapphire substrates 51 are divided surfaces having processed, the end faces 22 of the group III nitride semiconductor layers 2 are undivided surfaces having processed. Further, end faces of the mask 31 are divided by the laser processing. The end faces 22 of the group III nitride semiconductor layers 2 are located on positions inwardly retracted from the end faces of the mask 31.

FIG. 3 is a diagram for illustrating a method of manufacturing a nitride semiconductor device according to a second embodiment of the present invention, showing a step of forming division guide grooves substitutable for the step shown in FIG. 1(c). According to this embodiment, processing for forming division guide grooves 10 is performed with a diamond cutter 20. No group III nitride semiconductor layers 2 are formed on cutting lines 7 (see FIG. 2), on which a mask 31 is formed. Gaps g (20 μm each, for example) larger than the width (3 μm to 5 μm, for example) of the processing with the diamond cutter 20 are ensured between group III nitride semiconductor layers 2, 2 adjacent to one another through the cutting lines 7. The processing with the diamond cutter 20 is performed through the gaps g such that the division guide grooves 10 are formed to pass through the mask 31 and to reach portions of a prescribed depth (2 μm to 3 μm, for example) from a major surface of a sapphire wafer 5. The division guide grooves 10 are formed along the cutting lines 7.

Thus, the manufacturing steps can be simplified by forming the division guide grooves 10 with the diamond cutter 20. In order to form the division guide grooves 10 with the diamond cutter 20, however, the gaps g must be set to about 20 μm each. Therefore, the areas of the group III nitride semiconductor layers 2 in the individual device regions can be more widened in the case of forming the division guide grooves 10 by laser processing.

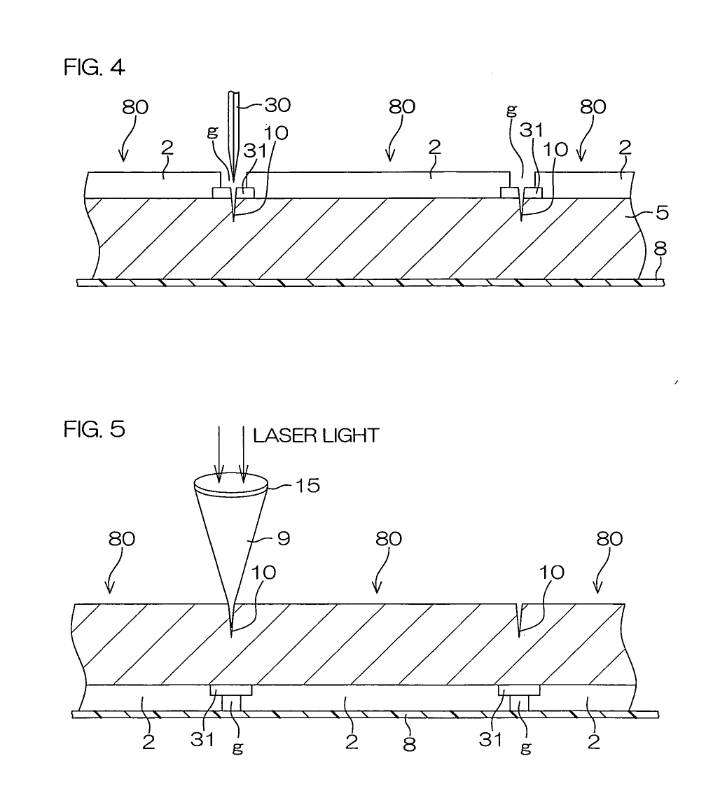

FIG. 4 is a diagram for illustrating a method of manufacturing a nitride semiconductor device according to a third embodiment of the present invention, showing a step of forming division guide grooves substitutable for the step shown in FIG. 1(c). According to this embodiment, processing for forming division guide grooves 10 is performed with a dicing saw 30. No group III nitride semiconductor layers 2 are formed on cutting lines 7, on which a mask 31 is formed. Gaps g (30 μm each, for example) larger than the width (20 μm, for example) of the processing with the dicing saw 30 are ensured between group III nitride semiconductor layers 2, 2 adjacent to one another through the cutting lines 7. The processing with the dicing saw 30 is performed through the gaps g such that the division guide grooves 10 are formed to reach a major surface of a sapphire wafer 5 through the mask 31 and to further reach portions of a prescribed depth (2 μm to 3 μm, for example) from the major surface of the sapphire wafer 5. The division guide grooves 10 are formed along the cutting lines 7.

When the division guide grooves 10 are formed with the dicing saw 30 in the aforementioned manner, the manufacturing steps can be more simplified as compared with the case of forming the division guide grooves 10 by laser processing. In order to form the division guide grooves 10 with the dicing saw 30, however, each gap g must be set to about 30 μm. Further, the width of the mask 31 must be increased to be larger than the gap g, if necessary. Therefore, the area of the group III nitride semiconductor layer 2 in each individual device region can be more widened in the case of forming the division guide grooves 10 by laser processing.

FIG. 5 is a diagram for illustrating a method of manufacturing a nitride semiconductor device according to a fourth embodiment of the present invention, showing a step of forming division guide grooves substitutable for the step shown in FIG. 1(c). According to this embodiment, division guide grooves 10 each having a prescribed depth (2 μm to 3 μm, for example) are formed on a major surface of a sapphire wafer 5 opposite to group III nitride semiconductor layers 2. The sapphire wafer 5 is transparent, and a mask 31 made of silicon oxide is also transparent. Therefore, gaps g can be observed through the sapphire wafer 5 and the mask 31 from the major surface of the sapphire wafer 5 opposite to the group III nitride semiconductor layers 2. Thus, when the positions of the gaps g are specified by imaging the sapphire wafer 5 with an image sensor such as a CCD camera from the side opposite to the group III nitride semiconductor layers 2, for example, the division guide grooves 10 can be formed along the specified positions of the gaps g.

Referring to FIG. 5, the division guide grooves 10 are formed with a laser processor. In other words, the group III nitride semiconductor layers 2 are opposed to a stage of the laser processor, and held on this stage through a support sheet 8. In this state, the sapphire wafer 5 is imaged with the image sensor from the side opposite to the group III nitride semiconductor layers 2. The gaps g are recognized from the acquired image of the sapphire wafer 5, and an X-Y stage mechanism of the laser processor is controlled on the basis of the result of this image recognition. Thus, the laser processor scans the sapphire wafer 5 with a laser beam 9 along cutting lines 7 (see FIG. 2), to form the division guide grooves 10 along the cutting lines 7.

While the four embodiments of the present invention have been described, the present invention may be embodied in other ways. While the method of manufacturing a nitride semiconductor device by growing the group III nitride semiconductor layer on the sapphire substrate has been described with reference to each of the aforementioned embodiments, another transparent substrate such as an SiC substrate or a group III nitride semiconductor substrate such as a GaN substrate may alternatively be employed as the substrate.

While the mask 31 is made of silicon oxide in each of the aforementioned embodiments, the mask 31 may alternatively be made of silicon nitride, tungsten, titania (titanium (IV) oxide) or the like.

While the division guide grooves 10 are formed up to intermediate portions of the sapphire wafer 5 in the thickness direction with the dicing saw 30 in the embodiment shown in FIG. 4, the division guide grooves 10 may alternatively be formed along the overall thickness direction of the sapphire substrate 5. Thus, the formation of the division guide grooves 10 with the dicing saw 30 and division of the sapphire wafer 5 can be performed through the same step.

While the division guide grooves 10 are formed on the major surface of the wafer opposite to the group III nitride semiconductor layers 2 by laser processing in the embodiment shown in FIG. 5, similar division guide grooves may alternatively formed with a diamond cutter or a dicing saw.

Further, division guide grooves along the cutting lines 7 may be formed on both major surfaces of the wafer 5 respectively.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2007-196424 filed in the Japanese Patent Office on Jul. 27, 2007, the disclosure of which is incorporated herein by reference in its entirety.

What is claimed is:

1. A method of manufacturing a nitride semiconductor device, comprising the steps of:
forming a mask of a pattern selectively covering a cutting line on a first major surface of a substrate;
forming group III nitride semiconductor layers exposing the mask provided on the cutting line by selectively growing a group III nitride semiconductor from exposed portions of the first major surface of the substrate;
forming a division guide groove on the substrate along the cutting line; and
dividing the substrate along the division guide groove.

2. The method of manufacturing a nitride semiconductor device according to claim 1, wherein
the step of forming the division guide groove includes a step of forming the division guide groove by laser processing.

3. The method of manufacturing a nitride semiconductor device according to claim 1, wherein
the step of forming the division guide groove includes a step of forming the division guide groove with a diamond cutter.

4. The method of manufacturing a nitride semiconductor device according to claim 1, wherein
the step of forming the division guide groove includes a step of forming the division guide groove by dicing.

5. The method of manufacturing a nitride semiconductor device according to claim 1, wherein
the step of forming the division guide groove includes a step of forming the division guide groove on the first major surface of the substrate.

6. The method of manufacturing a nitride semiconductor device according to claim 1, wherein
the step of forming the division guide groove includes a step of forming the division guide groove on a second major surface of the substrate.

7. The method of manufacturing a nitride semiconductor device according to claim 6, wherein
the substrate is a transparent substrate.

8. The method of manufacturing a nitride semiconductor device according to claim 7, wherein
the step of forming the division guide groove includes a step of setting a position for forming the division guide groove while observing a dividing line through the substrate from the side of the second major surface of the substrate.

9. The method of manufacturing a nitride semiconductor device according to claim 1, wherein
the substrate is made of a material other than a group III nitride semiconductor.

10. The method of manufacturing a nitride semiconductor device according to claim 1, wherein
the substrate is a sapphire substrate or an SiC substrate.

11. A nitride semiconductor device including:
a substrate;
a mask formed on an edge portion of a first surface of the substrate; and
a group III nitride semiconductor layer selectively grown from an exposed portion of the first major surface of the substrate, wherein
an end face of the substrate is a divided surface, and an end face of the group III nitride semiconductor layer is an undivided surface.

12. The nitride semiconductor device according to claim 11, wherein
an end face of the mask is a divided surface.

13. The nitride semiconductor device according to claim 11, wherein
the end face of the group III nitride semiconductor layer is located on a position inwardly retracted from an end face of the mask.
